(19) United States
(12) Patent Application Publication
(10) Pub. No.: US 2026/0120993 A1
(43) Pub. Date: Apr. 30, 2026

(54) SYSTEMS FOR AND METHODS OF IMPROVED PLASMA ENHANCED DEPOSITION, SURFACE MODIFICATION, AND ABATEMENT

(71) Applicant: Stellar Engiine, Inc., Los Altos, CA (US)

(72) Inventors: Kevin P. Fairbairn, Los Gatos, CA (US); Babak Adibi, Los Altos, CA (US)

(21) Appl. No.: 19/366,044

(22) Filed: Oct. 22, 2025

Related U.S. Application Data
(60) Provisional application No. 63/833,125, filed on Oct. 25, 2024.

(51) Int. Cl. H01J 37/248; H01J 37/24; H01J 37/32

(52) U.S. Cl. CPC H01J 37/248; H01J 37/241; H01J 37/32568; H01J 2237/3321

(57) ABSTRACT

A plasma-generating system produces highly reactive species and radicals for chemical processing. The system includes an array of plasma-producing applicators for generating a plasma within a processing cavity when excited by high voltages, a power source comprising one or more high voltage power supplies for generating high voltages, the one or more high voltage power supplies coupled to the array of plasma-producing applicators; a gas or vaporizer supply coupled to one side of the array of applicators; and an electronic controller for instructing the power source and the gas or vaporizer supply to turn on at selected times and at set operating levels to generate the plasma within the processing cavity, the electronic controller further for controlling relative motion, distance, orientation, or any combination thereof between the substrate and the array of plasma producing applicators.

### RELATED APPLICATION(S)

This application claims the benefit under 35 U.S.C. § 119(e) of co-pending U.S. Provisional Patent Application Ser. No. 63/833,125, titled “Apparatus and Method for Improved Plasma Enhanced Deposition and Surface Modification,” filed Oct. 25, 2024, which is hereby incorporated by reference in its entirety.

### FIELD OF THE INVENTION

The present invention relates generally to apparatus and methods for improving the quality of plasma enhanced material processing. Embodiments can be applied to deposition applications and beyond, including etching, sputtering to modify shape of films deposited on topology, surface cleaning, polymer or other film removal, surface modification including doping of the surface and sub-surface, and abatement of plasma by-products, with examples relating to Plasma Enhanced Atomic Layer Deposition (PEALD) provided.

### BACKGROUND OF THE INVENTION

PEALD has become a critical processing method for semiconductor devices at the nanometer scale for multiple process steps. Atomic Layer Deposition (ALD) consists of a series of process steps which are repeated until overall desired thickness is achieved. An example is silicon nitride ALD where:
Step 1: Precursor Deposition—A silicon containing precursor such as Silane (SiH₄) adsorbs onto the substrate surface. This step typically lasts less than one second.
Step 2: Purge—The chamber is purged with an inert gas (such as argon or nitrogen) to remove any unreacted precursor and by-products. This step typically lasts less than 2 seconds.
Step 3: Plasma Exposure—Nitrogen containing plasma, where the co-reactant gas, typically ammonia (NH₃) or a mixture of nitrogen and hydrogen (N₂/H₂), is introduced into the chamber. Plasma is preferred because it enhances the reactivity and allows for lower deposition temperatures compared to thermal ALD. The plasma, consisting of species and ions, reacts with the adsorbed precursor molecules on the surface, forming a self-limiting layer of silicon nitride with hydrogen incorporated, SiN-Hx. The plasma exposure time can range up to 10 seconds. Hydrogen is incorporated into the film principally due to the hydrogen content of the co-reactant gas.
Step 4: Purge—Another purge step follows to remove any remaining reactive species and by-products. This step lasts 1 to 2 seconds.

The cycle time for one complete PEALD step sequence, precursor, purge, plasma exposure and purge, typically takes 5 to 15 seconds. Multiple cycles are repeated to build up the desired thickness of the silicon nitride film. PEALD for silicon oxide follows the same process steps, with an oxygen-based co-reactant used.

An example of a PEALD application is patterning using self-aligned double patterning (SADP) where thermal budget and processing temperature considerations limit the use of thermal ALD. While PEALD for silicon oxide is well established, other desired ALD films such as silicon or other metal nitrides for liners and barriers remain challenging due to the difficulty of achieving good film quality, at reasonable cost and productivity levels, and conformally coat re-entrant features.

Film quality, usually characterized by wet etch rate, with lower etch rate being the goal, is significantly impacted by hydrogen incorporation into the film as described in Step 3 above. To avoid ALD film damage, the RF power applied, in a Direct Capacitively Coupled Plasma (CCP), is limited, otherwise the ion energy of the ions impacting the film can cause damage. The limited RF power is insufficient by a wide margin to ionize pure nitrogen used in a nitride PEALD processes; hence more readily ionized co-reactants such as ammonia are used.

The inability to conformally coat re-entrant features is due to the co-reactant plasma containing ions as well as reactive species. The ions when accelerated perpendicularly to the substrate surface by the plasma bias generated by the applied RF power, are not able to coat re-entrant features.

There are multiple types of PEALD process reactor types, some of which can improve some aspects of the Direct CCP PEALD deposited films; however they create new issues. Knoops et al.'s paper “Status and prospects of plasma-assisted atomic layer deposition”, J. Vac. Sci. Technol. A 37, 030902 (2019), illustrate the variety of PEALD reactors in use today, both in semiconductor production and R&D as reproduced in FIG. 1. The paper also lists which plasma generation reactor types are being provided by which equipment company. Overwhelmingly, Direct CCP is the preferred method provided by the major semiconductor equipment companies and utilized by device manufacturers. This is not surprising as the CCP method builds upon the semiconductor industry's preferred method for Plasma Enhanced Chemical Vapor Deposition (PECVD) which is Direct CCP with a shower head sitting directly above the substrate with RF power applied to the shower head or pedestal supporting the substrate. PECVD process pressure is typically 1 to 10 Torr which is like PEALD operating pressures, although some PEALD CCP process pressures can be as low as 0.1 Torr. This pressure range in conjunction with the typical shower head to substrate gap of <8 mm to 25 mm is a good compromise between the ability to strike plasma and achieve plasma uniformity and reasonable mass flow rates for fast deposition rates. Unfortunately, at typical PEALD or PECVD Direct CCP operating conditions, it is not possible to simply use nitrogen as a co-reactant when producing nitride compounds, due to insufficient ionization and creation of reactive species.

The issue of unwanted hydrogen incorporation in films involving silane SiH₄, and plasma processing is a long-standing problem. Applied Materials' US patent (U.S. Pat. No. 4,854,263 (1989)) discusses in some detail the issue, reporting concentration of hydrogen in PECVD deposited silicon nitride films as high as 25-30 atom percent when using ammonia. The Applied Materials patent discloses the use of conical shaped holes in the shower head above the substrate where the conical shape induces a hollow cathode effect which enhancers ionization, enabling some breakdown of nitrogen, avoiding the use of ammonia with the hydrogen incorporation in the deposited film reduced to 7-10 atomic percent. The problem with this approach is that the RF power drives a hot plasma in the conical holes which can lead to shorter shower head lifetime and significant expense for user of equipment. However, the approach does show the merits of nitrogen, and dissociation directly above the substrate for reducing hydrogen contamination in the deposited film.

FIG. 1 shows a variety of remote plasma PEALD reactors, 1001 to 1007, which are used mainly in R&D, illustrating both Temporal ALD and Wafer Position (Spatial) ALD, with one remote plasma type 1002 above the chamber and the other, radical enhanced 1003, creating a side flow over the substrate. The means of creating the remote plasma can be Capacitively Coupled Plasma 1004, Inductively Coupled Plasma (ICP) (1005), Hollow cathode (1006) or Electron Cyclotron Resonance (ECR) (1007) driven by microwave. These means are very effective at breaking down molecules including co-reactants such as nitrogen and delivering a high concentration of reactive species and very limited ions to the substrate. Unfortunately, the remote plasma techniques come with several significant shortcomings, such as non-uniform plasma at the substrate, high cost and low productivity, complexity, and film contamination. These techniques require low pressure, two to three orders of magnitude lower than CCP, to function. They provide a “point source” of plasma into the process reactor which relies on diffusion to achieve uniformity with typically richer plasma species in the center versus the edge of substrate. Achieving low pressures requires expensive vacuum components such as turbopumps and large gate valves. Expense and complexity are further increased by the cost of the remote plasma generating hardware. The low-pressure operation results in lower mass flow rates to the substrate thus reducing productivity versus CCP. The film contamination is due to the partial pressure of water, which is always present in typical ALD reactors using polymer O-rings and reactor body temperatures below 400 degrees Celsius, being a significant proportion of the total vacuum pressure leading to unwanted oxygen contamination in non-oxide films.

One PEALD reactor type 1004 as illustrated in FIG. 1 uses CCP with a grid between the plasma and the substrate. The issue with this type of reactor is that the grid holes cause recombination of the plasma species as they pass through the grid. Also, the RF driven CCP is still limited in its ability to break down molecules such as nitrogen.

From the description of the prior art above, the legacy toolbox of plasma producing techniques is not adequate to meet all the requirements of PEALD. There is a need for an innovative plasma generating solution that both provides the benefits of Direct CCP while addressing its shortcomings in the field of ALD.

### SUMMARY OF THE INVENTION

Unlike the prior art, embodiments of the disclosure use a solution that goes against conventional wisdom and principles in plasma reactor design, such as avoiding plasma light up in holes and avoiding recombination of ions and reactive species on the walls of a hole. Embodiments create the plasma in a hole, or cavity as described in this disclosure, with the cavity wall being part of the plasma creation process.

Embodiments in this disclosure utilize the principle of micro discharges operating in a manner to create a homogeneous non equilibrium “cold” plasma in a cavity and near the outlet of the cavity. In some embodiments, the cavity described is circular in cross section; however in other embodiments, the cavity can be slot shaped, oval or polygonal or combinations of such shapes. The micro-plasma generator, or “applicator,” comprises one or a multiplicity of electrodes where voltages can be applied to one or more electrodes with one or more electrodes at ground potential. An applicator in accordance with some embodiments utilizes the principle of a Dielectric Barrier Discharge, “DBD,” where one or more electrodes is shielded from the plasma by a dielectric barrier. The plasma generated by the applicator is composed of neutral species, reactive species, and ions and electrons. Unlike traditional plasma excitation methods used in plasma processing such as CCP or ICP, DBD plasmas produce a significant density of electrons versus ions resulting in a low temperature plasma. The copious amounts of electrons drive the creation of a large percentage of reactive species relative to ions. The electron density is relatively low but with a large fraction of highly energetic electrons, which cause electron impact dissociation and formation of metastable species, i.e., cause chemical activation of the precursor gas (R T Nguyen-Smith et al, Plasma Sources Sci. Technol. 31 (2022) 035008, 16pp). In some embodiments, the low temperature is important as it both helps the plasma generation process and avoids excessive heat into the plasma-generating hardware which could lead to premature hardware failure.

Some embodiments further combine multiple applicators into an array, analogous to a showerhead, which can produce a wide area uniform plasma, situated in front of the substrate being processed. The fabrication of this applicator array, especially when the array contains hundreds to thousands of applicators, is a major engineering and manufacturing challenge requiring significant invention and ingenuity. Plasma repeatability from applicator to applicator is critically important to produce wide area plasma uniformity requiring accurate dimensional control, material property control and the lamination of metal ceramic metal layers which can withstand the process regimes.

A major challenge that some embodiments address is the avoidance of plasma breakdown to individual concentered plasma filaments or arcs within the DBD applicator, both of which can lead to process variability or particulate contamination on the substrate or applicator failure. The dielectric barrier provides some protection against plasma breakdown by limiting the discharge current; however, as voltage increases, the dielectric barrier is not sufficient protection. If the dielectric barrier is too thick, then that requires undesirable higher input voltage and power requirements from the voltage generator. Furthermore, the dielectric surface plays a role in the plasma creation. Surface charges accumulate on the dielectric surface as soon as a discharge is ignited in the gas. Surface charges create an electric field potential which counteracts the externally applied voltage, resulting in self-limitation of the discharge current. Despite the two mechanisms provided by the dielectric barrier to limit plasma breakdown, it is not always sufficient. The applied voltage magnitude, duration and voltage profile over time can have a profound impact on creating a stable homogeneous plasma in the applicator. It has been demonstrated that instead of using sinusoidal high voltage as was the conventional approach in DBD applications such as ozone generators, the use of very short microsecond or nanosecond or shorter time scale high voltage pulses can under certain operating conditions; such as high voltage slew rate, pressure, temperature, gas species and flow rates, and depending on the applicator design, avoid plasma filaments or arcs and produce uniform homogeneous plasmas. This invention utilizes sub 100 nanometer high voltage slew time pulses operating in the 1 to 1000 kHz repeating range, with either fixed pulse to pulse voltage amplitude or varying high voltage amplitude pulse to pulse.

Some embodiments utilize additional steps to minimize the chance of undesirable breakdown of the plasma to intense plasma filaments or arcs by careful manipulation of the pulsed high voltage amplitude. Firstly, the first high voltage pulse that ignites the plasma is higher in amplitude with the subsequent pulses lower in amplitude by 5% to 90%, as sustaining the plasma and growing the reactive radical density requires a smaller electric field than that required for ignition. This reduced electrical field reduces the chance of undesirable plasma breakdown. Secondly, voltage amplitude of subsequent pulses is varied by up to 40% on either a random basis or preprogrammed pattern. One mechanism that can lead to undesired plasma breakdown is repeated micro discharges to the same surface spot which locally heats up and causes a runaway plasma filament leading to arcing. By varying the electric field from pulse to pulse, this changes the discharge conditions, avoiding repetitive small micro discharges in the same spot on the applicator surface.

The reactive species produced by the nanosecond scale pulse have significantly longer lifetime with millisecond time scale decay times. Some embodiments utilize this feature by the pumping up of reactive radical species concentrations by subsequent pulses, at periods less than the decay time until a saturation level is achieved. Some embodiments utilize optimized high voltage pulse repeat frequency to maximize reactive species while avoiding overdriving the plasma which is wasteful on energy and can lead to heating the applicator, resulting in plasma breakdown.

The dielectric surface condition of the inside of the applicator has a direct bearing on the plasma produced in terms of reactive species generated, all other parameters being the same. Additionally, as discussed above, the surface condition can affect the breakdown of the plasma to an undesirable state. In accordance with some embodiments, a further inventive step is to ensure consistent surface conditions by using a conditioning, “seasoning”, process step periodically, either before each PEALD step or every 5 to 100 or more substrates processed or after the periodic process reactor cleaning step, where both the precursor and the co-reactant flow at the same time, with pulsed power applied, to deposit a seasoning thin film on the surface of the applicator cavity. In addition to creating a consistent surface condition, the coated surface is the same compound that is to be deposited as an ALD film on the substrate, reducing the likelihood of contamination from the dielectric applicator material.

A majority of prior art in DBD technology utilizes single cylinder geometry, at atmosphere pressure, to produce a jet like plasma which is advantageous for treating small areas of the body such as teeth roots or for treating skin wounds. A jet like plasma is not good for achieving a uniform plasma over a substrate as it will produce a non-uniform polka dot pattern. Some embodiments of the invention avoid plasma jets by using axial changes in diameter of the plasma cavity to create a broad and expanding plasma plume at the exit of the applicator. The exit of the applicator, including a final electrode, is profiled, to create an expanding gas cloud combined with a curvature in the electric field within the applicator to redirect electrons from a trajectory parallel to the axis of the applicator and thus create more reactive species off axis of the applicator cavity.

Process pressures for legacy direct CCP processing, whether PEALD or PECVD, are typically in the range 1 to 10 Torr with a few outliers at 0.1 Torr driven by ease in igniting the plasma. DBD applicator processing pressures in contrast are capable of operating over a much greater range, from atmosphere to very low pressure, by adjusting high voltage pulsing parameters and electrical field distribution within the applicator cavity. A vast majority of research and applications of DBD plasma technology have been at atmosphere due to the economic desire to avoid the cost and complexity of vacuum equipment, plus the desire to apply the DBD technology to medical treatments. Atmospheric processing would be very advantageous to semiconductor processing for economic reasons. Different embodiments can both satisfy existing vacuum-based applications and provide a solution for atmospheric and close to atmospheric processing.

In some instances, it is beneficial to bombard the substrate using energized ions to aid the deposition process to achieve certain film material properties such as film stress. In direct CCP, the RF applied power ignites and sustains the plasma and simultaneously creates a bias voltage across the plasma sheath above the substrate. A downside of direct CCP is that the plasma density and ion bias voltage are directly coupled, making process adjustments more challenging. While RF may be used in conjunction with the DBD applicator created plasma, it is not ideal. Firstly, the application of RF jeopardizes the stability of the DBD plasma. Secondly, RF produced bias always creates a bi-modal bias ion energy distribution which is not ideal when dealing with fragile films such as an ALD deposited film. Two embodiments are disclosed to create and control the desired bias ion energy. In one embodiment, a shaped voltage profile, where change of voltage with time is constant, is applied to the pedestal, which can be a heater or electrostatic chuck, holding the substrate. The linear change of voltage with time is converted by the capacitance of the pedestal and wafer to a steady DC bias above the wafer, resulting in a narrow distribution in the ion energy for the substrate bombarding ions. Periodically the charge built up in the pedestal and substrate capacitors must be discharged. This discharge period, typically a few microseconds, can be synchronized as to coincide with a period when the applicator array is not being pulsed. This is advantageous as it avoids any interaction between the high voltage pulse generator and the power supply providing the shaped voltage to the pedestal.

A second embodiment for creating fixed energy ions provides an exit electrode which can be DC biased to extract ions at a fixed energy. The bias applied can vary from a few volts to up to 70 kV and be pulsed out of phase with the nanosecond pulses. The higher energy ions are for alternative implementations of the embodiments such as directly implanting ions into the substrate surface, using sputtering with heavy ions such as Argon to modify the shape of deposited films over topology, substrate cleaning and surface conditioning, and substrate etching applications

Further embodiments add additional electrodes to allow staged plasma creation with a first stage to provide pre-ionization, and second or more stages can be used for plasma density enhancement or ion energy modification.

Uniformity of process results across a substrate is a critical process parameter. Some embodiments sub-divide the array of applicators into zones which can be independently powered and positioned with different high voltage pulse regimes to adjust the uniformity of the plasma across the substrate. This is another advantage over traditional RF driven deposition processes where adjusting applied RF power across a showerhead is limited to very large area faceplates as used in flat panel processing and is not feasible for 300 mm or smaller substrate diameters.

Some embodiments further enable the creation of novel compounds, such as nitride compounds beyond silicon nitride, by PEALD, a result that cannot be accomplished with current CCP methods.

This disclosure describes improvements to the state of the art for PEALD thin film processing. The same principles of disclosed embodiments, with modifications that will be apparent to one skilled in the art after reading this disclosure, can also be applied to PECVD applications where improved film quality is desired. Additionally, embodiments of this invention can also be applied to applications beyond deposition, including etching, sputtering to modify shape of films deposited on topology, surface cleaning, polymer or other film removal, and surface modification including doping of the surface and sub-surface and subsequent abatement of plasma process by-products.

Embodiments can also be used to clean the process reactor by use of suitable cleaning gases such as, but not limited to, NF₃ or hydrogen.

Principles realized in the embodiments can be extended from circular cavities to slots where the slot length is significantly longer than the width of the slot. Other embodiments can utilize rows of long slots, including a single slot, for either processing in a static position or where the slotted applicator moves relative to the substrate in a pass-by processing manner.

Furthermore, the term substrate includes not only rigid objects such as wafers and dielectric or metal sheets, but it also refers to flexible objects such as flexible dielectric and metal films or foils, polymers and textiles, to name only a few examples.

In a first aspect, a plasma-generating system for producing highly reactive species and radicals for chemical processing comprises an array of one or more plasma-producing applicators for generating a plasma within a processing cavity containing a substrate; a power source comprising one or more high voltage power supplies for generating high voltages, the one or more high voltage power supplies coupled to the array of plasma-producing applicators; a gas or vaporizer supply coupled to one side of the array of plasma-producing applicators; and an electronic controller for controlling the power source and the gas or vaporizer supply to turn on at selected times and at set operating levels to generate the plasma within the processing cavity, the electronic controller further for controlling relative motion, distance, orientation (e.g., titled/angled), or any combination thereof between the substrate and the array of plasma producing applicators.

In one embodiment, the high voltages comprise a first pulsed high voltage. In one embodiment, an amplitude of the first pulsed high voltage is in a range of 1 kV to 30 kV. In one embodiment, a forward skew time of the first pulsed high voltage is <100 ns. In one embodiment, the high voltages further comprise a second pulsed high voltage that follows the first pulsed high voltage, wherein an amplitude of the second pulsed high voltage is in a range 5% to 50% lower than the initial gas breakdown of the amplitude of the first pulsed high voltage.

In one embodiment, the high voltages include ongoing pulses after gas breakdown that vary in voltage amplitude by up to 40% on a programmed basis. In one embodiment, the high voltages include ongoing pulses after gas breakdown that vary in voltage amplitude by up to 40% on a random basis.

In one embodiment, the electronic controller causes the plasma to be ignited via an auxiliary method and then sustained by pulsed voltages from the power source. In one embodiment, the array of plasma-producing applicators contains between 1 and 500,000 applicators over an area of at least 300 mm².

In one embodiment, applicators within the array of plasma-producing applicators contain holes that are cylindrical, slotted, or a combination of both. In one embodiment, applicators within the array of plasma-producing applicators have shapes optimized for boundary fill fraction, perimeter density, or both.

In one embodiment, the array of plasma-producing applicators is sub-divided into zones with each zone independently powered by a pulsed high voltage from the power source and position adjusted.

In one embodiment, applicators within the array of plasma-producing applicators comprise two or more electrodes. In one embodiment, an applicator in the array of plasma-producing applicators comprises three-electrodes, and further, a middle electrode of the three electrodes is powered by pulsed high voltages from the power source with other two electrodes at or near ground potential. In one embodiment, an applicator in the array of plasma-producing applicators comprises three-electrodes, and further, the applicator exit electrode is powered by nano-pulsed high voltages from the power source with an amplitude up to 40 kV. In one embodiment, an applicator in the array of plasma-generating applicators comprises a series of four sequentially spaced electrodes, and further, the applicator exit electrode is grounded with the one of the previously spaced electrode powered by pulsed high voltages from the power source. In one embodiment, the sequentially spaced electrodes are powered by the pulsed high voltages out of phase. In one embodiment, adjacent ones of the sequentially spaced electrodes are powered by different ones of the high voltage power supplies.

In one embodiment, an applicator in the array of plasma-generating applicators comprises a multi-electrode configuration, and further, a first set of electrodes in the multi-electrode configuration pre-ionize the gas which is further ionized by subsequent combinations of electrodes.

In one embodiment, the applicators in the array of plasma-generating applicators comprise one electrode isolated from the generated plasma by a dielectric barrier and the other electrode is directly exposed to plasma. In one embodiment, an exposed electrode has a smaller aperture area than the isolated barrier electrode aperture.

In one embodiment, the electronic controller is programmed to deposit a film periodically inside a cavity of an applicator in the array of plasma-producing applicators to condition a surface for consistency.

In one embodiment, the plasma-generating system is coupled to a Metrology equipment for monitoring the health and operating condition of the system, the plasma, or both, and to provide feedback for reporting and displaying the condition.

In a second aspect, a plasma reactor for chemical processing of a workpiece, the plasma reactor comprises a chamber comprising a cavity for containing a workpiece during processing; a pedestal within the cavity for supporting the workpiece; an array of plasma-producing applicators within the chamber; a gas/vapor inlet for introducing gas or vapor to the array of plasma-producing applicators; and a high-voltage generator coupled to the array of plasma-producing applicators, wherein, when gas or vapor that has been introduced to the array of plasma-producing applicators is excited by the voltage generator according to a voltage pattern, the array of plasma-producing applicators generates a plasma within the cavity.

In one embodiment, the plasma reactor further comprises an electronic controller operatively coupled to the high-voltage generator, to the gas/vaporizer inlet, and to the pedestal, the electronic controller for controlling the introduction and parameters of the gas to the array of plasma-producing applicators, for controlling the voltage pattern, and for controlling an orientation of the pedestal within the cavity.

In one embodiment, the voltage pattern is programmed. In another embodiment, the voltage pattern is random.

### BRIEF DESCRIPTION OF THE DRAWINGS

The embodiments described herein will be better understood from the detailed description given further below and from the appended drawings, which are meant to illustrate and not to limit the disclosure. In the drawings, the same label refers to the same or a similar element.

FIG. 1 shows prior art PEALD plasma reactors in use today in semiconductor production and R & D.

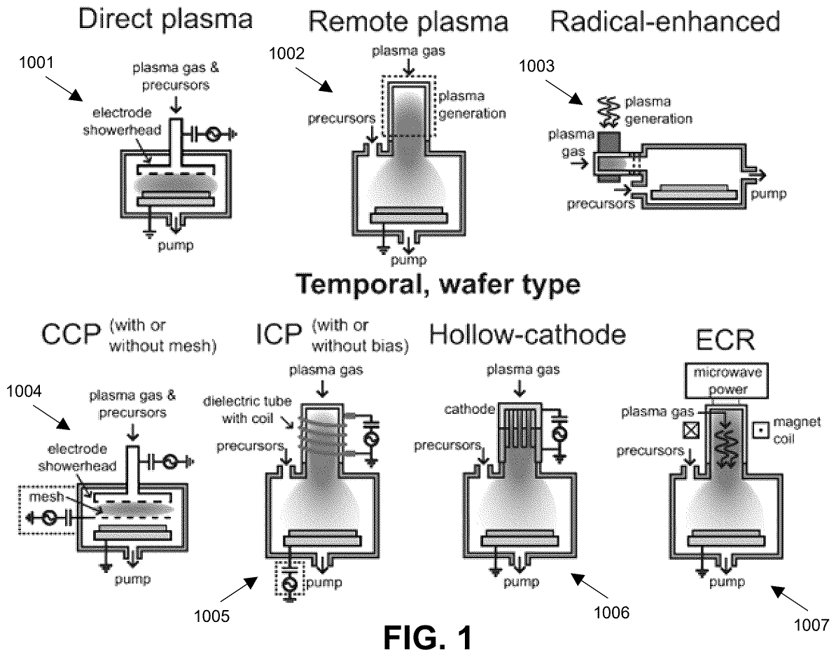

FIG. 2 shows a cross-sectional view of a PEALD plasma reactor, according to some embodiments.

FIGS. 3A, 3B, 3C and 3D show cross-sections of alternative micro-plasma generating DBD applicators according to some embodiments.

FIGS. 4A and 4B show a cross-section of a micro-plasma generating DBD applicator and a corresponding representation of the applicator to illustrate dimensions, according to some embodiments.

FIGS. 5A and 5B show illustrative ninety-degree quadrant views of the face of an applicator array for circular and slot shaped applicators, respectively, according to some embodiments.

FIG. 6 shows a top view of the face of an applicator array with circular shaped applicators and five separate powered zones, according to some embodiments.

FIGS. 7A and 7B show top views of a section of applicator arrays with three applicators showing two alternative high voltage electrode connection schemes, respectively, according to some embodiments.

FIG. 8 shows a graph plotting two nanosecond scale high voltage pulses with the defining parameter metrics versus time, according to some embodiments.

FIGS. 9A and 9B show graphs plotting two alternative high voltage pulse sequences versus time, respectively, according to some embodiments.

FIG. 10 shows a graph plotting the synchronized high voltage plasma generating pulses and voltage waveform versus time applied to a pedestal and a resulting DC bias above a substrate, according to some embodiments.

FIG. 11 shows the steps of a method for processing a substrate, according to some embodiments.

### DETAILED DESCRIPTION OF THE DRAWINGS

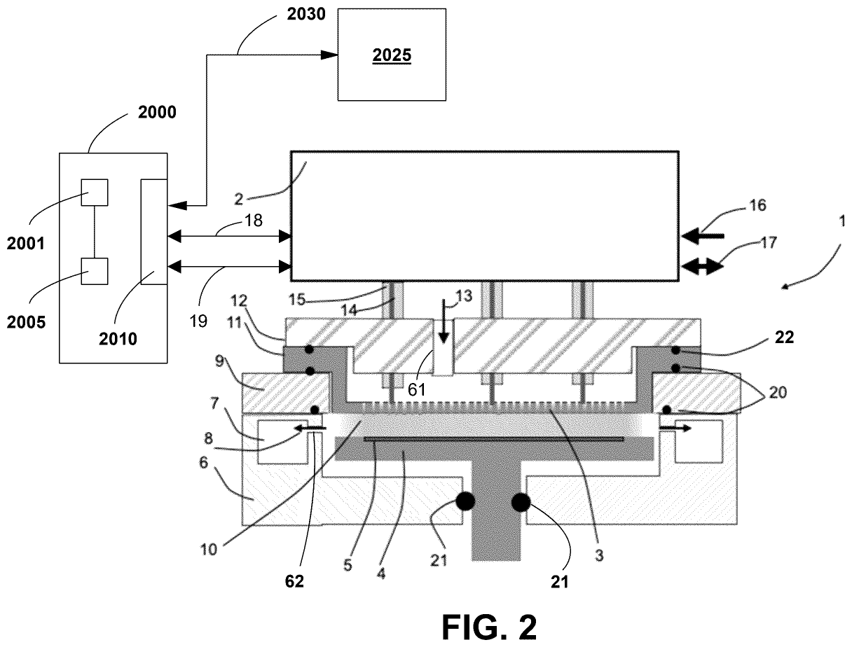

FIG. 2 shows a cross-sectional view of a PEALD plasma reactor (process reactor) 1, according to some embodiments. The nanosecond time scale pulsed high voltage generator 2, is mounted over the inlet gas box lid assembly 12, and coupled to the array of micro-plasma DBD applicators 3 by one or more high voltage connector(s) 14 and high voltage feedthroughs and support insulators 15. The number of high voltage connections can vary from one to twenty (20) or more, depending on the number of independently controlled applicator zones. Other embodiments may locate the pulsed high voltage generator 2 remotely and use cables to couple to the high voltage connector(s) 14. Substrate 5 sitting on the substrate pedestal 4 is located below the applicator array 3. The substrate pedestal 4 is within the process reactor body 6 with gases 8 removed from the chamber through a gas outlet 62 by the pumping channel 7 which is coupled to an exhaust pump (not shown). The substrate pedestal 4 can move up and down driven by an external lift mechanism (not shown) to adjust the gap between the substrate 5 and the applicator array 3, Additionally the pedestal 4 can be rotated either concentrically or not concentrically to improve uniformity of the substrate's exposure to plasma. Vacuum seal 21 isolates the pedestal 4 from external atmosphere. Process reactor top flange 9 provides support to the applicator array support flange 11 and provides vacuum sealing in conjunction with an O ring seal on the lower and upper faces of the flange 9. The applicator array 3 is mechanically coupled to the applicator support flange 11 and provides the ground return path for the pulsed generator 2. In some embodiments, the applicator array 3 and the applicator support flange 11 are integrated into a single part. The inlet gas box lid 12 and associated O ring vacuum seal 22 sit on the applicator array support flange 11. Gas 13 is piped into the inlet gas box lid 12 from a suitable gas control module (not shown) through a gas inlet 61. In some embodiments a baffle plate with holes (not shown) may be placed between the gas inlet 61 and the top of the applicator array 3.

The nanosecond pulsed high voltage generator 2 receives AC or DC power through connection 16, water cooling inlet and outlet through connection 17 if water cooling is preferred method of removing heat, receives and transmit information and instructions through connection 18 and a two-way synchronization signal from connection 19. A microcontroller 2000 associated with the process reactor 1 provides the commands, synchronization and communications with the high voltage generator 2. The microcontroller 2000 includes a processor 2001, computer-readable media 2005 coupled to the processor 2001 and containing computer-executable instructions executable by the processor 2001, and a communications module 2015 coupled to the connections 18 and 19 for exchanging data and instructions with the high voltage generator 2. As explained in more detail below, in some embodiments, the microcontroller 2000 is able to execute the computer-executable instructions to control the high voltage generator 2, as described herein; to raise, lower, and rotate, the pedestal 4; control the flow of gas to the gas/vapor inlet 61 and from the outlet 62; transmit synchronization signals, as described below, and to perform other functions for processing a substrate 5, in accordance with the principles of the embodiments, to name only a few functions. In some embodiments, the high voltage generator 2 may also provide fixed DC voltage to the outlet electrode of the applicator array 3, and/or provide a shaped DC wave form to the pedestal 4 to create an ion bias over the substate. When the applicator array 3 is powered by the high voltage generator 2 with desired high voltage pulses, and the desired gas 13 is admitted to the process reactor 1 at desired process pressure, a plasma 10 is created above the substrate 5.

In some embodiments, the microcontroller 2000 is coupled to Metrology equipment 2025 (such as a Langmuir Probe to measure the properties of plasma or a Spectrometer, supplied by Ocean Optics) over a channel 2030. As known to those skilled in the art, Metrology equipment is used to monitor the health and operating condition of the reactor 1, its components parts as shown in FIG. 2, including any generated plasma.

While the microcontroller 2000 is shown including one processor 2001 and one computer-readable media 2005, it will be appreciated that the microcontroller 2000 is merely illustrative and can include any number of processors, computer-readable, where any of the processor(s) and computer-readable media are local to remaining components of the reactor 1, remote from the reactor 1, or both. In other embodiments, other functionally equivalent components are used in place of or in addition to the processor 2001 and the computer-readable media 2005. As but one example, an application specific integrated circuit is substituted for the processor 2001 and the computer-readable medium 2005. Those skilled in the art will recognize other functionally equivalent components that can be used to practice the embodiments.

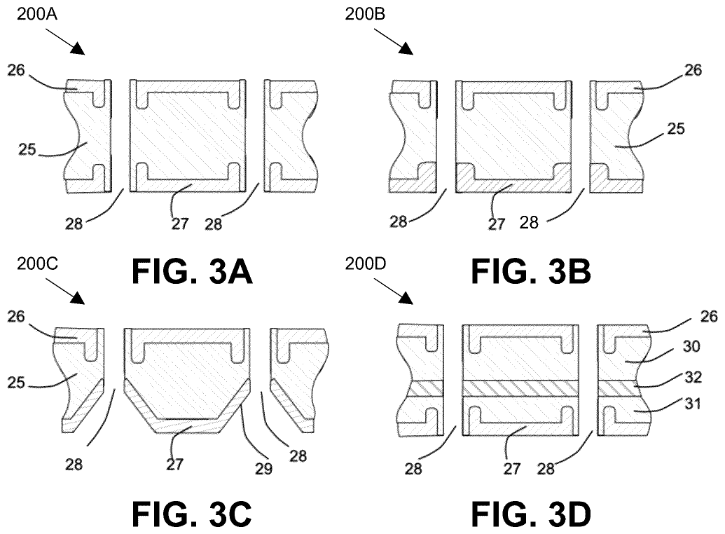

In accordance with alternative embodiments, FIGS. 3A, 3B, 3C and 3D show cross-sections of micro-plasma generating DBD applicators, 200A, 200B, 200C, and 200D, respectively, contained within the applicator array 3. In FIG. 3A, illustrating applicator 200A, the applicator high voltage electrode 26 is shown on the top of the dielectric barrier body 25 with the ground electrode 27 located at the bottom. Both the high voltage electrode 26 and ground electrode 27 are insulated from the plasma channel 28. In FIGS. 3A, 3B, 3C and 3D, illustrating the applicators 200B, 200C, and 200D, respectively, the dielectric barrier body 25 can be alumina or quartz or silicon nitride or zirconia or other suitable dielectric material for the process application supported by the applicator. In some embodiments, the dielectric barrier body 25 may be composed of a lightly doped semiconductor material such as silicon. Several methods could be utilized to fabricate the structure of the applicators 200A, 200B, 200C, and 200D. In one method, a circular disc of the chosen dielectric material could have the electrode profiles in the dielectric material created by use of masks and material removal using fine drilling or sand or water blasting. The electrodes can be deposited using electroplating the bulk thickness and capping with a suitable chemical resistive layer. For example, copper could be electroplated with the seed layer applied by either sputtering, dip coating or chemical vapor deposition. Nickel could be used as a protective layer, and if further chemical resistance on the exposed surfaces of the electrodes is required, a suitable dielectric film such as silicon nitride could be deposited. The plasma cavity 28 could be fabricated either before or after deposition of the metal electrodes utilizing known ceramic material fabrication methods such as water cutting. If the cavity 28 is created before the deposition of the metal electrodes, masking can be used to shield the cavity 28 from the electrode creation steps. Chemical mechanical polishing may also be employed to ensure flatness, dimensional and surface finish requirements.

The applicator 200B as shown in FIG. 3B is similar to applicator 200A shown in FIG. 3A, except that the applicator 200B has no dielectric barrier between the ground or exit electrode 27 and the plasma cavity 28. An advantage of this configuration is that the underside of the applicator array can present a continuous ground electrode, with the exception of plasma cavity holes or slots, to the plasma 10 above the substrate 5.

The applicator 200C as shown in FIG. 3C is similar to the applicator 200B shown in FIG. 3B except that the applicator 200C has a flared or other shaped outlet to the ground or exit electrode 29 section of the plasma cavity 28. An advantage of this configuration is in addition to the underside of the applicator array presenting a continuous ground electrode, with the exception of plasma cavity holes or slots, to the plasma 10, the structure now has the additional advantage of creating an expanding plasma plume due to the expansion in the gas cloud created by the flared outlet. The combination of multiple adjacent expanding plasma plumes contributes to improved uniformity of plasma above the substrate. The profile of the ground electrode flared outlet may be straight as shown or curved. Furthermore, the inside diameter of the ground electrode flared outlet may be smaller than the diameter of the high voltage electrode.

The applicator 200D, as shown in FIG. 3D is similar to the applicator 200A shown in FIG. 3A except that the applicator 200D has an additional intermediate electrode 32 between a top dielectric body 30 and a lower dielectric body 31. In some embodiments, multiple intermediate electrodes may be used. The dielectric material may differ for the top dielectric body 30 and the lower dielectric body 31. This configuration can be utilized in multiple advantageous ways. In one configuration, the intermediate electrode 32 may be at ground potential and the exit at a fixed DC voltage to create ions of equal energy. The DC voltage, both positive or negative, may be low, less than 100 volts or as high as 100 kV DC for ion implant applications. An alternative configuration applies pulsed high voltage out of phase to two, or more electrodes if there is more than one intermediate electrode, to create optimized electrical fields for plasma creation and control of the ion and reactive radicals' levels and ratios, and an improved margin against undesirable plasma breakdown into damaging filaments and arcs. In another embodiment, with two intermediate electrodes, the plasma is created between the top electrode and next electrode, which is at ground potential, with the third electrode at a DC voltage with the last electrode at ground to provide a plasma focusing effect. The configuration/features in the applicator 200D can be combined with the configuration/features in the applicators 200B and 200C to advantageous effect.

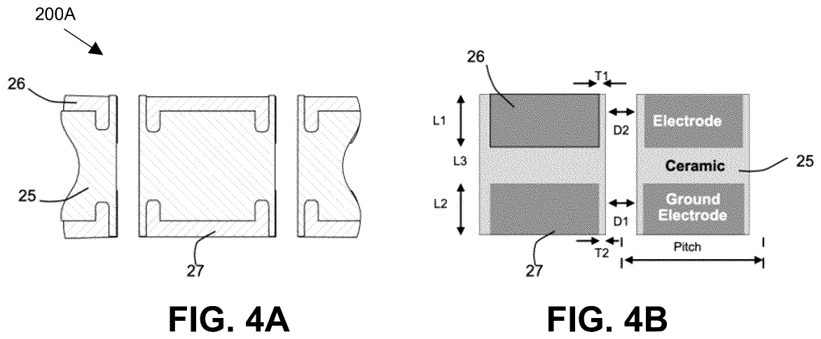

FIGS. 4A and 4B show a cross-section of a micro-plasma generating DBD applicator 200A and a corresponding representation of the applicator with dimension definitions, respectively, which can serve as reference to the detailed dimensions utilized in this disclosure. Given that the applicators may be utilized across a range of process applications and operating conditions, in particular vacuum to atmospheric pressures, and different gases and flow rates, the dimensions will encompass large ranges.

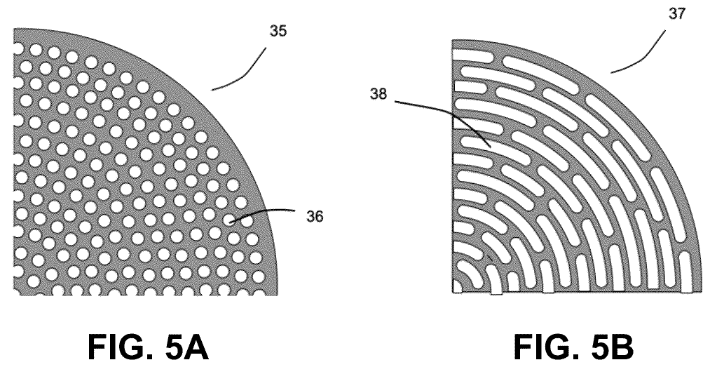

FIGS. 5A and 5B show illustrative views of the face of the applicator array 5 for circular 35 and slot shaped 37 applicator cavities respectively. In some embodiments, circular cross section plasma creation channels 36 are used, which can be important in certain plasma regimes, where trying to maximize dielectric surface impact on maintaining a homogeneous plasma. In another embodiment, slots 38 are used. Slots have the advantage over circular cavities in that the volume-to-surface area is maximized, which can be important in certain plasma regimes, where trying to minimize the impact of surface reactive species recombination. For other applications, these arrays could be in rectangular format with circular or straight slotted openings or staggered circular or slotted openings (not shown here), as the array can be extended to cover larger format substrates.

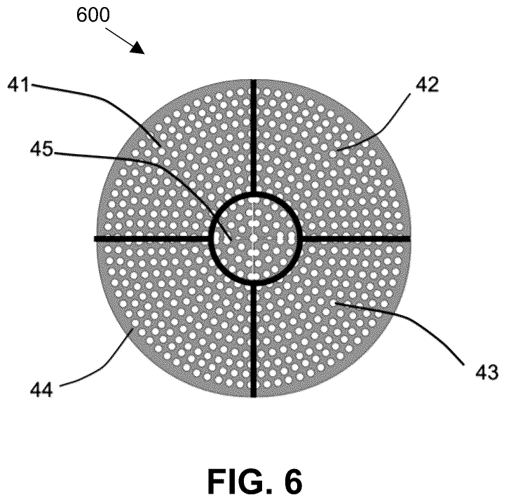

FIG. 6 shows an illustrative view of the face of an applicator array 600 with circular shaped applicators and five (5) separate powered zones, in accordance with some embodiments. Uniformity of films created by PEALD as in PECVD is a critical process parameter. As much as designers try to achieve uniformity through design, invariably uniformity requires a combination of process parameter tradeoffs, such as adjusting the gap between the substrate and the shower head or flow rate or pressure. Some embodiments solve the uniformity problem by segmenting the applicator array 600 into zones 41 to 45 which can be individually powered by separate voltage feeds from the high voltage generator 2 (e.g., as controlled by microcontroller 2000) or each segment be positioned at a different gap with respect to the substrate 5 or be shaped as a convex or concave dome or complex shaped surfaces. FIG. 6 shows a single center zone 45 and four outer quadrant zones 41-44. After reading this disclosure, those skilled in the art will recognize that other zone quantities and patterns can be created, for example a series of concentric rings around a center round zone, in accordance with some embodiments.

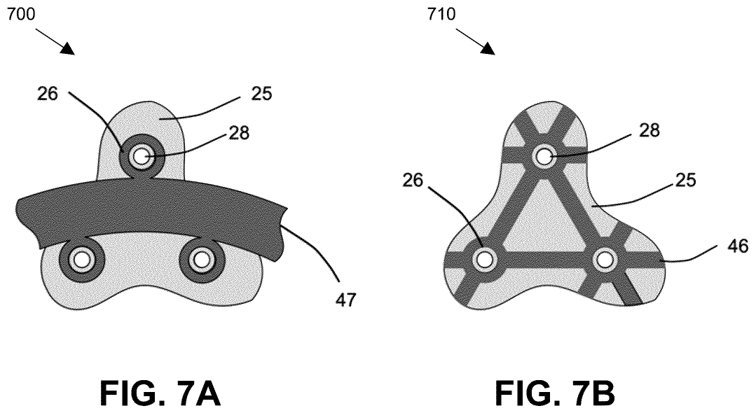

FIGS. 7A and 7B show the top sides of sections of two applicator arrays 700 and 710 with three applicators showing two alternative high voltage electrode 26 connection schemes respectively, according to embodiments. The connections between the applicators 46 and 47 (for arrays 710 and 700, respectively) do not cover the whole top surface of either array, rather they are laid out in a manner to minimize capacitance coupling with the ground electrode, or DC electrodes if present, to avoid unwanted power loss due to dissipation effects.

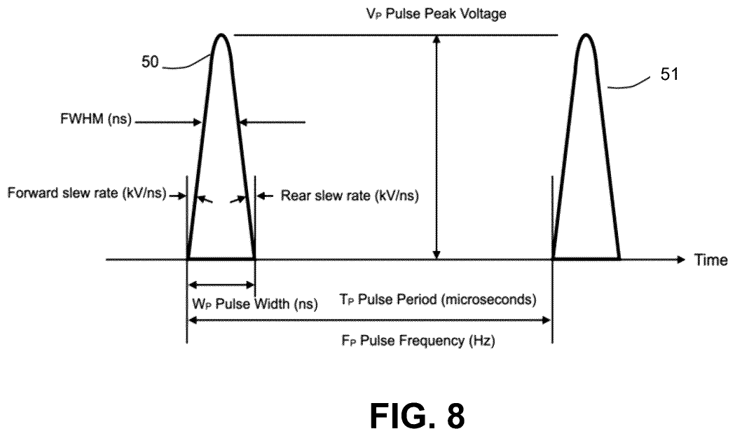

FIG. 8 shows a graph of two nanosecond scale high voltage pulses 50 and 51 over time with the defining parameter metrics. In some embodiments, pulse parameters operate within the following ranges: Wp pulse width from 5 ns to 200 ns, forward and rear slew rates from 0.2 kV/ns to 10 kV/ns, FWHM or full width half magnitude 3 ns to 180 ns, V_{P} pulse peak voltage from 0.5 kV to 50 kV, and F_{P} pulse frequency from 1 kHz to 1000 kHz with T_{P} pulse period equal to 1/F_{P}. The higher V_{P}, pulse peak voltages, are associated with higher pressures or very low vacuum pressures.

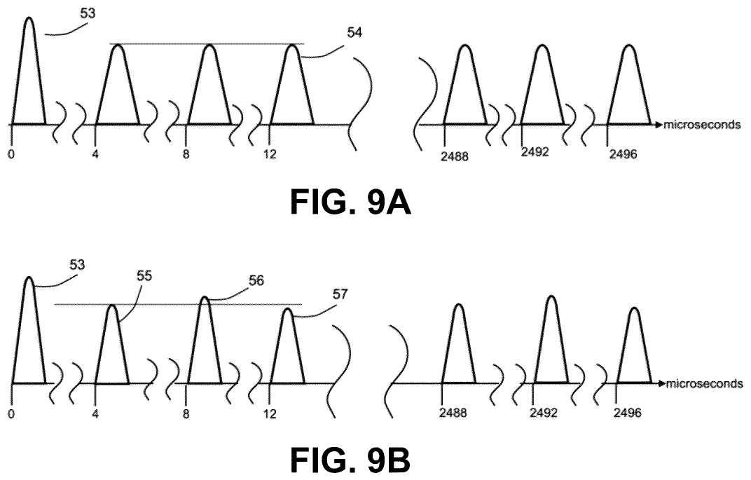

FIGS. 9A and 9B show examples of pulsed high voltage applied to an applicator, or multiple applicators, in accordance with embodiments, depending on the zone configuration of the applicator array, for a total time of 2500 microseconds at a frequency of 250 kHz or 4 microsecond period. In one embodiment, as shown in FIG. 9A, a single high voltage pulse 53 ignites plasma in applicator cavity 28 and is followed by reduced voltage amplitude pulses 54 (e.g., a voltage pattern or voltage train) to maintain and drive the creation of higher density plasma and reactive radicals. While one initial plasma ignition pulse is illustrated, in some cases, there may be several initial pulses of equal magnitude until plasma is established. The pulse width and slew rate may also vary with the higher voltage magnitude pulses having shorter widths and faster slew rates to avoid undesirable plasma breakdown. FIG. 9B illustrates a further enhancement of the pulse train shown in FIG. 9A with pulses 55, 56 and 57, following the ignition pulse 53 or pulses, being driven at reduced and varying voltage magnitudes to further avoid undesirable plasma breakdown.

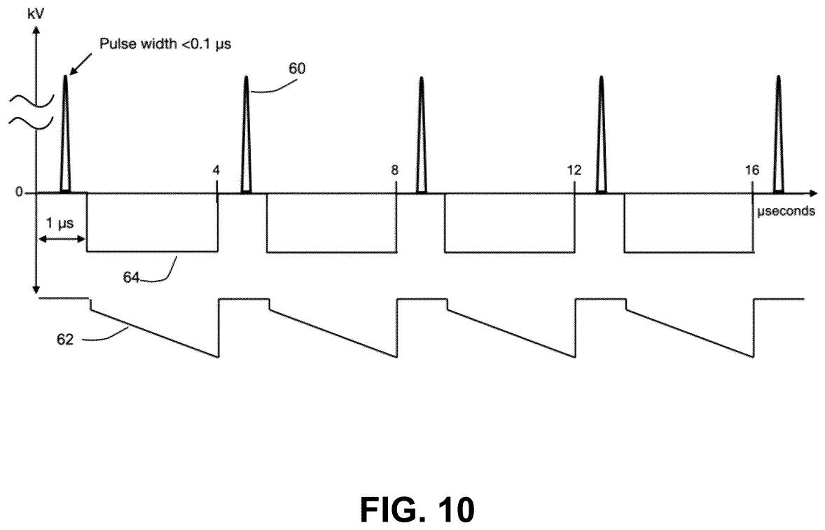

FIG. 10 shows the voltage profiles and timing when a non-RF power induced bias voltage is created above the substate 5, in accordance with some embodiments. In this illustrative embodiment, the voltage pulses 60 have a 450 kHz repetition rate with a pulse duration less than 0.1 microseconds. The shaped voltage waveform 62 is applied to the pedestal 4 which in turn creates a negative DC bias voltage above the substrate due to the capacitance of the pedestal and substrate 5 which converts the steady change in voltage with time to a fixed voltage waveform 64. Periodically, in this example every 4 microseconds or 250 kHz, the voltage waveform 62 drops to zero volts or to an even slightly positive voltage to allow the charge build up in the pedestal 4 and substrate 5 capacitance to dissipate. Using a synchronization signal between the high voltage pulse generator and bias power supply, the high voltage pulse is energized when the shaped waveform is at zero or close to zero volts. This ensures no electrical interaction with the plasma in the applicator cavity when the high voltage pulse is applied thus avoiding the potential for undesirable plasma breakdown to damaging filaments or arcs. The lifetime of ions and reactive radicals is several milliseconds at atmospheric pressure and even longer at low pressures, so ions are present in the plasma above the substrate during the bias voltage on phase. While this example is for a synchronous situation when high voltage pulse and bias voltage are operating at the same frequency, the same principle applies when in the non-synchronous mode where either the pulse high voltage period T_{P} or the bias voltage period can be dithered using the synchronization signal to ensure the pulse occurs while the bias voltage is zero or close to zero.

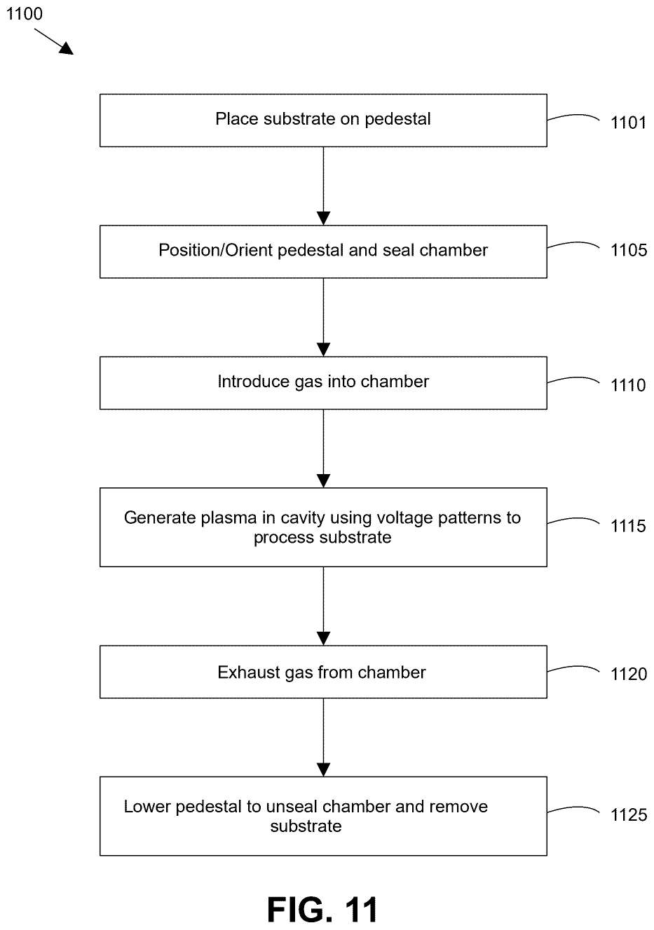

In accordance with some embodiments, FIG. 11 shows the steps 1100 of a method of processing a substrate 5 in the plasma reactor 1. In a step 1101, the substrate 5 is placed on the pedestal 4. In a step 1105, the pedestal 4 is positioned to seal the processing cavity. In a step 1110, a gas is introduced through the gas inlet 61. In a step 1115, the pulsed high voltage generator 2 generates voltage patterns (e.g., voltage profiles) to ignite the gas to generate plasma in the cavity, to maintain the plasma with the cavity, to bias the pedestal 4, or to perform any combination of these or similar steps to thereby process the substrate 5. In a step 1120, when the processing is complete, the gas is exhausted from the cavity through the gas outlet 62. In a step 1125, the pedestal 4 is lowered to unseal the processing cavity, and the substrate 5 is removed from the plasma reactor 1.

It will be appreciated that in some embodiments, the steps 1100 are all controlled by the processor 2001 executing the instructions stored on the computer-readable media 2005. It will be appreciated that the steps 1100 are merely illustrative. In other embodiments, some steps can be added, some deleted, or both, to name only a few examples.

While some embodiments describe operating a system at vacuum to process substrates, it will be appreciated that in other embodiments the system can operate at atmosphere or at other conditions to achieve the required processing. In still other embodiments, such as for a single (e.g., inline) application, no process chamber is required.

While for sake of ease of understanding, a positive high voltage pulse has been described. In practice, the pulse may be of negative polarity, and in some embodiments the high voltage electrodes relative to ground electrode positions reversed relative to the flow direction or facing the workpiece.

To those skilled in the art to which this invention relates, many changes in construction and widely differing embodiments and applications will make themselves known without departing from the spirit and scope of the invention, as defined by the appended claims. The disclosure and the description herein are purely illustrative and are not intended to be in any sense limiting.

What is claimed is:

1. A plasma-generating system for producing highly reactive species and radicals for chemical processing comprising;
an array of one or more plasma-producing applicators for generating a plasma within a processing cavity containing a substrate;
a power source comprising one or more high voltage power supplies for generating high voltages, the one or more high voltage power supplies coupled to the array of plasma-producing applicators;
a gas or vaporizer supply coupled to one side of the array of plasma-producing applicators; and
an electronic controller for control the power source and the gas or vaporizer supply to turn on at selected times and at set operating levels to generate the plasma within the processing cavity, the electronic controller further for controlling relative motion, distance, orientation, or any combination thereof between the substrate and the array of plasma producing applicators.

2. The plasma-generating system of claim 1, wherein the high voltages comprise a first pulsed high voltage.

3. The plasma-generating system of claim 2, wherein an amplitude of the first pulsed high voltage is in a range of 1 kV to 40 kV.

4. The plasma-generating system of claim 2, wherein a forward skew time of the first pulsed high voltage is <100 ns.

5. The plasma-generating system of claim 2, wherein the high voltages further comprise a second pulsed high voltage that follows the first pulsed high voltage, wherein an amplitude of the second pulsed high voltage is in a range 5% to 50% lower than the initial gas breakdown of the amplitude of the first pulsed high voltage.

6. The plasma-generating system of claim 1, wherein the high voltages include ongoing pulses after gas breakdown that vary in voltage amplitude by up to 40% on a programmed basis.

7. The plasma-generating system of claim 1, wherein the high voltages include ongoing pulses after gas breakdown that vary in voltage amplitude by up to 40% on a random basis.

8. A plasma-generating system of claim 1, wherein the electronic controller causes the plasma to be ignited via an auxiliary method and then sustained by pulsed voltages from the power source.

9. The plasma-generating system of claim 1, wherein the array of plasma-producing applicators contains between 1 and 500,000 applicators over an area of a 300 mm² wafer or larger.

10. The plasma-generating system of claim 1, wherein applicators within the array of plasma-producing applicators contain holes that are cylindrical, slotted, or a combination of both.

11. The plasma-generating system of claim 1, wherein applicators within the array of plasma-producing applicators have shapes optimized for boundary fill fraction, perimeter density, or both.

12. The plasma-generating system of claim 1, wherein the array of plasma-producing applicators is sub-divided into zones with each zone independently powered by a pulsed high voltage from the power source and position adjusted.

13. The plasma-generating system of claim 1, wherein applicators within the array of plasma-producing applicators comprise two or more electrodes.

14. The plasma-generating system of claim 11, wherein an applicator in the array of plasma-producing applicators comprises three-electrodes, and further wherein a middle electrode of the three electrodes is powered by pulsed high voltages from the power source with other two electrodes at or near ground potential.

15. The plasma-generating system of claim 11, wherein an applicator in the array of plasma-producing applicators comprises three-electrodes, and further wherein the applicator exit electrode is powered by nano-pulsed high voltages from the power source with an amplitude up to 40 kV.

16. The plasma-generating system of claim 11, wherein an applicator in the array of plasma-generating applicators comprises a series of four sequentially spaced electrodes, and further wherein the applicator exit electrode is grounded with a previously spaced electrode, the electrodes powered by pulsed high voltages from the power source.

17. The plasma-generating system of claim 16, wherein the sequentially spaced electrodes are powered by the pulsed high voltages out of phase, using different high voltage power supplies.

18. The plasma-generating system of claim 11, wherein an applicator in the array of plasma-generating applicators comprises a multi-electrode configuration, and further wherein a first set of electrodes in the multi-electrode configuration pre-ionize the gas which is further ionized by subsequent combinations of electrodes.

19. The plasma-generating system of claim 1, wherein the applicators in the array of plasma-generating applicators comprise one electrode isolated from the generated plasma by a dielectric barrier and the other electrode is directly exposed to plasma.

20. The plasma-generating system of claim 19, wherein an exposed electrode has a smaller aperture area than the isolated barrier electrode aperture.

21. The plasma-generating system of claim 1, wherein the electronic controller is programmed to deposit a film periodically inside a cavity of the applicators in the array of plasma-producing applicators to condition the surface for consistency.

22. The plasma-generating system of claim 1, wherein the plasma-generating system is coupled to a Metrology equipment for monitoring the health and operating condition of the system, the plasma, or both, and to provide feedback for reporting and displaying the condition.

23. A plasma reactor for chemical processing of a workpiece, the plasma reactor comprising:
a chamber comprising a cavity for containing a workpiece during processing;
a pedestal within the cavity for supporting the workpiece;
an array of plasma-producing applicators within the chamber;
a gas/vapor inlet for introducing gas or vapor to the array of plasma-producing applicators; and
a high-voltage generator coupled to the array of plasma-producing applicators,
wherein, when gas or vapor that has been introduced to the array of plasma-producing applicators is excited by the voltage generator according to a voltage pattern, the array of plasma-producing applicators generates a plasma within the cavity.

24. The plasma reactor of claim 23, further comprising an electronic controller operatively coupled to the high-voltage generator, to the gas/vaporizer inlet, and the pedestal, the electronic controller for controlling the introduction and parameters of the gas to the array of plasma-producing applicators, for controlling the voltage pattern, and for controlling an orientation of the pedestal within the cavity.

25. The plasma reactor of claim 24, wherein the voltage pattern is programmed.
